(19) United States
(12) Patent Application Publication
(10) Pub. No.: US 2012/0192912 A1
(43) Pub. Date: Aug. 2, 2012

(54) SOLAR CELL MODULE WITH EXTENDED AREA ACTIVE SUBCELL

(75) Inventors: Hsieh-Hsin YEH, Taipei County (TW); Chung-Pui Chan, Hong Kong (HK)

(73) Assignee: Du Pont Apollo Limited, Hong Kong (HK)

(21) Appl. No.: 13/015,587

(22) Filed: Jan. 28, 2011

(51) Int. Cl. H01L 31/042

(52) U.S. Cl. 136/244

(57) ABSTRACT

A solar cell array and a solar cell module with an extended area (Generally by increasing the width) active subcell are described. The solar cell array includes a fixing beam, at least one solar cell module and a fixing clip for fixing the at least one solar cell module on the fixing beam. The solar cell module further includes a dummy area formed on an edge of the solar cell module, a first active subcell formed next to the dummy area, and a second active subcell formed next to the first active subcell. The area of the first active subcell is larger than the area of the second active subcell to compensate for an area of the fixing clip overlapping on the first active subcell.

### FIELD OF THE INVENTION

The present invention generally relates to a solar cell module. More particularly, this invention relates to a solar cell module with an extended width active subcell.

### BACKGROUND OF THE INVENTION

Solar cell arrays are used for a variety of purposes, including for use as a utility interactive power supply, as a power supply for remote radiotelephone station, or to power an unattended monitoring station, for example.

The solar cell array includes one or more solar cell modules, arranged in arrays, attached to a supporting surface, and interconnected with electrical wiring to switches, inverters, battery chargers and batteries, etc. The solar cell module typically includes a plurality of active subcells and a dummy area cut by the laser beam. The dummy area is used to fix the solar cell module on a fixing beam with clips. If the dummy area is too large, the area of the active subcells of the solar cell module is reduced. Therefore, the output power efficiency of the solar cell module is reduced. If the dummy area is too small, the solar cell module has to be fixed on the fixing beam with more clips. Therefore, the assembly cost of the solar cell array is increased. Hence, there is a need to increase the output power efficiency of the solar cell module and reduce the assembly cost of the solar cell array.

### SUMMARY OF THE INVENTION

One objective of the present invention is to provide a solar cell module with an extended width active subcell which is in the active area to improve the output power efficiency of the solar cell module and increase the mechanical fixing strength for fixing the solar cell module on a fixing beam.

To achieve these and other advantages and in accordance with the objective of the present invention, as the embodiment broadly describes herein, the present invention provides a solar cell array or a solar cell module with an extended width active subcell. The solar cell array includes a fixing beam, at least one solar cell module and a fixing clip for fixing the at least one solar cell module on the fixing beam. The solar cell module further includes a dummy area formed on an edge of the solar cell module, a first active subcell formed next to the dummy area, and a second active subcell formed next to the first active subcell. The area (Generally by increasing the width) of the first active subcell is larger than the area of the second active subcell.

The area of the first active subcell is larger than the area of the second active subcell to compensate for an area of the fixing clip overlapping on the first active subcell. For example, an area of the first active subcell minus an area of the second active subcell is larger than or equal to an area of the fixing clip overlapping on the first active subcell.

In addition, the fixing clip includes an engaging portion to fix the solar cell module on the fixing beam. Therefore, the length of the engaging portion of the fixing clip is larger than a width of the dummy area. In a preferred embodiment, the length of the engaging portion of the fixing clip is about 28.4 millimeter (mm), the width of the dummy area is about 20.4 millimeter (mm), the fixing clip overlaps the first active subcell about 8 millimeter (mm), the width of the first active subcell is about 11 millimeter (mm). The width of the second active subcell is about 9 millimeter (mm). Therefore, the solar cell module of the present invention can gain about 1.2% active area compared with the conventional solar cell module.

Hence, the solar cell module with an extended area active subcell of the present invention can gain more active area to improve the output power efficiency of the solar cell module and also increase the mechanical fixing strength for fixing the solar cell module on a fixing beam.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates an embodiment of a solar cell array according to the present invention;

FIG. 2 illustrates a detailed part view of a solar cell module of the embodiment of the solar cell array according to the present invention; and

FIG. 3 illustrates a detailed part view of a conventional solar cell module.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

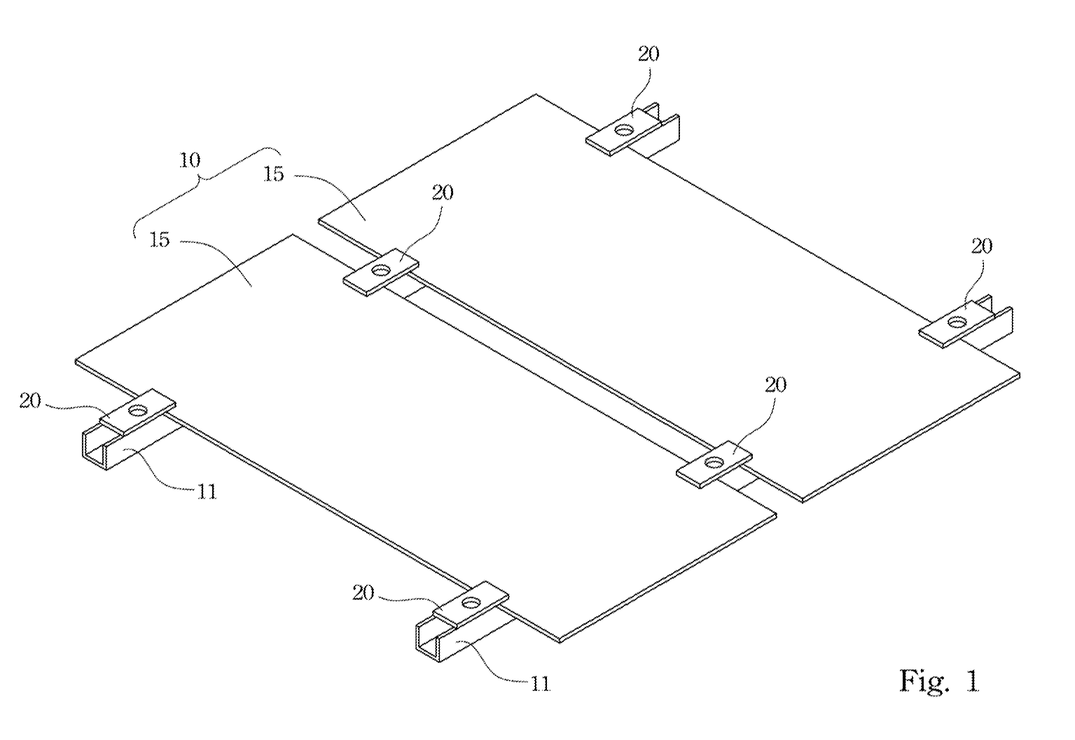

Refer to FIG. 1. FIG. 1 illustrates an embodiment of a solar cell array according to the present invention. The solar cell array 10 includes a plurality of solar cell modules 15, a plurality of fixing beams 11, and a plurality of fixing clips 20 for fixing the solar cell modules 15 on the fixing beams 11.

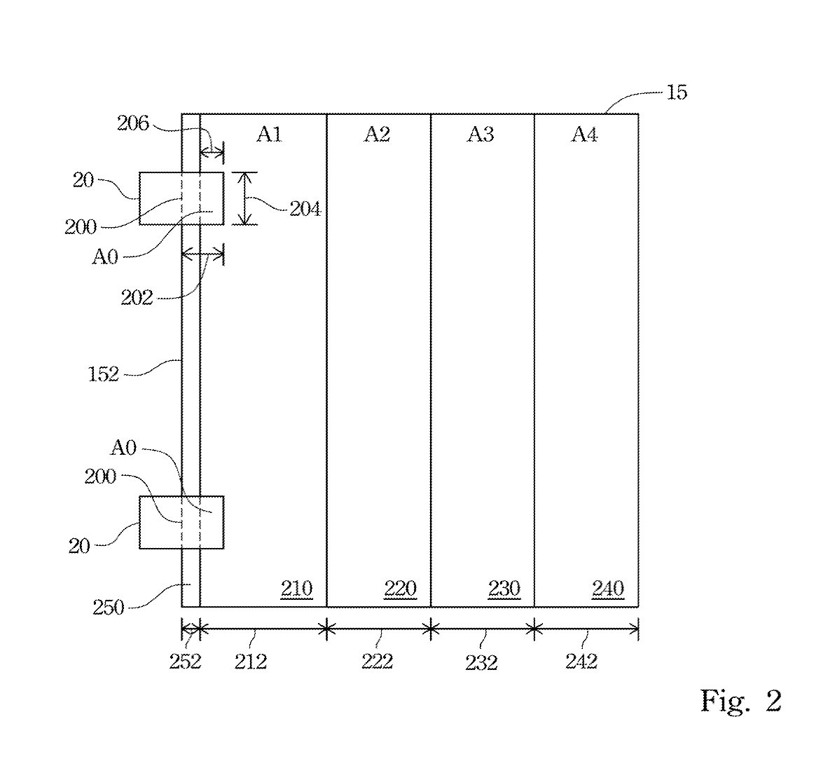

Further refer to FIG. 2. FIG. 2 illustrates a detailed part view of a solar cell module of the embodiment of the solar cell array according to the present invention. The solar cell module 15 includes a plurality of active subcells, e.g. a first active subcell 210, a second active subcell 220, a third active subcell 230, a fourth active subcell 240, and a dummy area 250. Clips 20 are utilized to fix the solar cell module 15 on the fixing beam 11. The fixing clip 20 includes an engaging portion 200. The engaging portion 200 of the fixing clip 20 extends from the edge 152 of the solar cell module 15 through the dummy area 250 to the first active subcell 210, and the engaging portion 200 of the fixing clip 20 fixes the solar cell module 15 to the fixing beam 11 to form the solar cell array 10.

Because the fixing clip 20 overlaps the first active subcell 210, the width 212 of the first active subcell 210 is extended to enlarge the area of the first active subcell 210. Therefore, the first active subcell 210 can provide the output power the same as or larger than the output power of the second active subcell 220, the third active subcell 230 or the fourth active subcell 240. The width 222 of the second active subcell 220 normally equals to the width 232 of the third active subcell 230, and also equals to the width 242 of the fourth active subcell 240. The width 212 of the first active subcell 210 is larger than the width 222 of the second active subcell 220, the width 232 of the third active subcell 230 and the width 242 of the fourth active subcell 240.

The area A0 of the fixing clip 20 overlapping the first active subcell 210 is about the length 206 times the height 204. The area A1 of the first active subcell 210 minus the area A0 is equal to or larger than the area A2 of the second active subcell 220, the area A3 of the third active subcell 230 and the area A4 of the fourth active subcell 240. Since area of the area (A1−A0) is equal to or larger than the area A2, A3 or A4, the active area of the first active subcell 210 is equal to or larger than the active area of the second active subcell 220, the active area of the third active subcell 230, or the active area of the fourth active subcell 240. Accordingly, the total output power of the solar cell module 15 is improved.

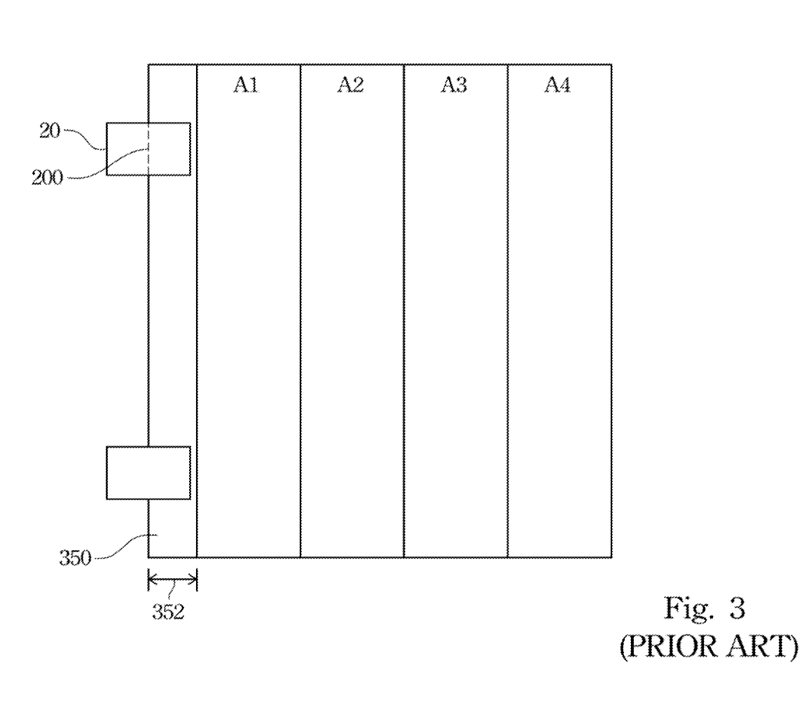

For example, if the length 202 of the engaging portion 200 of the fixing clip 20 is about 28.4 millimeter (mm), the width 252 of the dummy area 250 is about 20.4 mm and the width 212 of the first active subcell 210 is about 11 mm. Compared with the conventional solar cell module shown in FIG. 3, as the width 352 of the dummy area 350 has to be larger than 28.4 mm, the total active area of the solar cell module 15 of the present invention can gain about 1.2% active area more than that of the conventional solar cell module shown in FIG. 3. Accordingly, the solar cell module with an extended width active subcell of the present invention can gain more active area to improve the output power of the solar cell module and also increase the mechanical fixing strength for fixing the solar cell module on a fixing beam.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A solar cell array, comprising:
a fixing beam;
at least one solar cell module; and
a fixing clip for fixing the at least one solar cell module on the fixing beam, wherein the at least one solar cell module further comprises:
a dummy area formed on an edge of the solar cell module;
a first active subcell formed next to the dummy area; and
a second active subcell formed next to the first active subcell, wherein the area of the first active subcell is larger than the area of the second active subcell to compensate for an area of the fixing clip overlapping on the first active subcell.

2. The solar cell array of claim 1, wherein the fixing clip comprises an engaging portion to fix the solar cell module on the fixing beam.

3. The solar cell array of claim 2, wherein a length of the engaging portion of the fixing clip is larger than a width of the dummy area.

4. The solar cell array of claim 3, wherein the length of the engaging portion of the fixing clip is about 28.4 millimeter (mm).

5. The solar cell array of claim 4, wherein the width of the dummy area is about 20.4 millimeter (mm).

6. The solar cell array of claim 5, wherein the fixing clip overlaps the first active subcell about 8 millimeter (mm).

7. The solar cell array of claim 1, wherein a width of the first active subcell is about 11 millimeter (mm).

8. The solar cell array of claim 7, wherein a width of the second active subcell is about 9 millimeter (mm).

9. The solar cell array of claim 8, further comprising a third active subcell, wherein a width of the third active subcell is about 9 millimeter (mm).

10. The solar cell array of claim 1, wherein an area of the first active subcell minus an area the second active subcell is larger than or equal to an area of the fixing clip overlapping on the first active subcell.

11. A solar cell module, comprising:
a dummy area formed on an edge of the solar cell module;
a first active subcell formed next to the dummy area; and
a second active subcell formed next to the first active subcell, wherein the area of the first active subcell is larger than the area of the second active subcell to compensate for an area of a clip overlapping on the first active subcell for fixing the solar cell module to a fixing beam.

12. The solar cell module of claim 11, wherein the width of the dummy area is about 20.4 millimeter (mm).

13. The solar cell module of claim 12, wherein the fixing clip overlaps the first active subcell about 8 millimeter (mm).

14. The solar cell module of claim 13, wherein a width of the first active subcell is about 11 millimeter (mm).

15. The solar cell module of claim 14, wherein a width of the second active subcell is about 9 millimeter (mm).

16. The solar cell module of claim 15, further comprising a third active subcell.

17. The solar cell module of claim 16, wherein a width of the third active subcell is about 9 millimeter (mm).

18. The solar cell module of claim 11, wherein an area of the first active subcell minus an area the second active subcell is larger than or equal to an area of a clip overlapping on the first active subcell.
